(19) United States
(12) Patent Application Publication
(10) Pub. No.: US 2024/0145351 A1
(43) Pub. Date: May 2, 2024

(54) METHOD OF MANUFACTURING SEMICONDUCTOR DEVICES, CORRESPONDING SEMICONDUCTOR DEVICE, ASSEMBLY AND SUPPORT SUBSTRATE

(71) Applicant: STMicroelectronics S.r.l., Agrate Brianza (MB) (IT)

(72) Inventors: Matteo DE SANTA, Mezzago (IT); Mauro MAZZOLA, Calvenzano (BERGAMO) (IT)

(73) Assignee: STMicroelectronics S.r.l., Agrate Brianza (MB) (IT)

(21) Appl. No.: 18/384,524

(22) Filed: Oct. 27, 2023

(30) Foreign Application Priority Data
Nov. 2, 2022 (IT) 102022000022422

(51) Int. Cl. H01L 23/495; H01L 21/48; H01L 23/00; H05K 1/18; H05K 3/34

(52) U.S. Cl. CPC H01L 23/49548; H01L 21/4842; H01L 24/45; H01L 24/48; H01L 24/85; H05K 1/181; H05K 3/3426; H01L 21/561

(57) ABSTRACT

A semiconductor die is arranged on a first surface of a leadframe having a first thickness between the first surface and a second surface opposite the first surface and an array of electrically conductive leads. Terminal recesses are provided in the electrically conductive leads in the array at the first surface. At the terminal recesses, the electrically conductive leads have a second thickness less than the first thickness. The semiconductor die is coupled with the electrically conductive leads via wires or ribbons having ends coupled to the electrically conductive leads arranged in the terminal recesses. The leadframe is partially cut starting from the second surface at the terminal recesses with a cutting depth between the first thickness and the second thickness. The partial cut produces exposed surfaces of the electrically conductive leads and the ends of the electrically conductive elongated formations providing wettable flanks for solder material.

### PRIORITY CLAIM

This application claims the priority benefit of Italian Application for Patent No. 102022000022422 filed on Nov. 2, 2022, the content of which is hereby incorporated by reference in its entirety to the maximum extent allowable by law.

### TECHNICAL FIELD

The description relates to manufacturing semiconductor devices.

Solutions as described herein can increase the reliability of Quad-Flat No-Leads (QFN) packages, such as, for instance power QFN packages, for automotive products.

### BACKGROUND

So-called wettable flanks in semiconductor device packages are desirable for facilitating automatic optical inspection of solder joints after assembly on a mounting surface (a printed circuit board (PCB) for instance).

Wettable flanks of increased height are particularly desirable; however, wettable flank height may be limited to half the leadframe thickness if half-etched tie bars are provided during packaging to keep leads in place.

Also, defects in wedge contact between wire/ribbon and a corresponding lead may result in a failure of the whole unit, e.g., due to issues related to wire bonding, notably weld off/weld lift.

There is a need in the art for solutions aimed at addressing the issues discussed in the foregoing.

### SUMMARY

One or more embodiments relate to a method.

One or more embodiments relate to a corresponding semiconductor device.

One or more embodiments relate to a corresponding assembly (a semiconductor device plus a mounting member therefor, e.g., a printed circuit board (PCB).

One or more embodiments relate to a support substrate (e.g., a leadframe for use in manufacturing semiconductor devices).

Solutions as described herein provide a leadframe design and wire bonding scheme for wettable flanks (e.g., for Quad-Flat No-Leads (QFN) packages) that increases the total height of the wettable flanks while also providing an additional and direct electrical path between wire/ribbon and solder joint in case of weld failure.

Solutions as described herein may include leads comprising half-etched, outwards extending recessed portion.

Solutions as described herein contemplate providing a leadframe, mounting a die thereon, forming electrical connections between the die and leads in the leadframe through wire/ribbon bonding.

In solutions as described herein a second bond is formed in the recessed portion of the lead and a wire/ribbon tail extends outwardly of the recessed portion.

In solutions as described herein an encapsulation is molded and partial sawing of leads facilitates forming wettable flanks.

In solutions as described herein, partial sawing extends into the wire/ribbon tail and exposes a flank portion thereof.

In solutions as described herein tin plating of the partially cut leads and exposed portion of wire/ribbon follows.

Solutions as described herein facilitate wettable flanks/solder join inspection, e.g., package flank optical inspection (a wire/ribbon section is visible on package sides) and/or package X-ray inspection (where recessed lead portions are visible).

### BRIEF DESCRIPTION OF THE DRAWINGS

One or more embodiments will now be described, by way of example only, with reference to the annexed figures, wherein:

FIG. 1 is a partial cross-sectional view through a semiconductor device;

FIG. 2 is a partial perspective view showing certain possible details of the semiconductor device of FIG. 1;

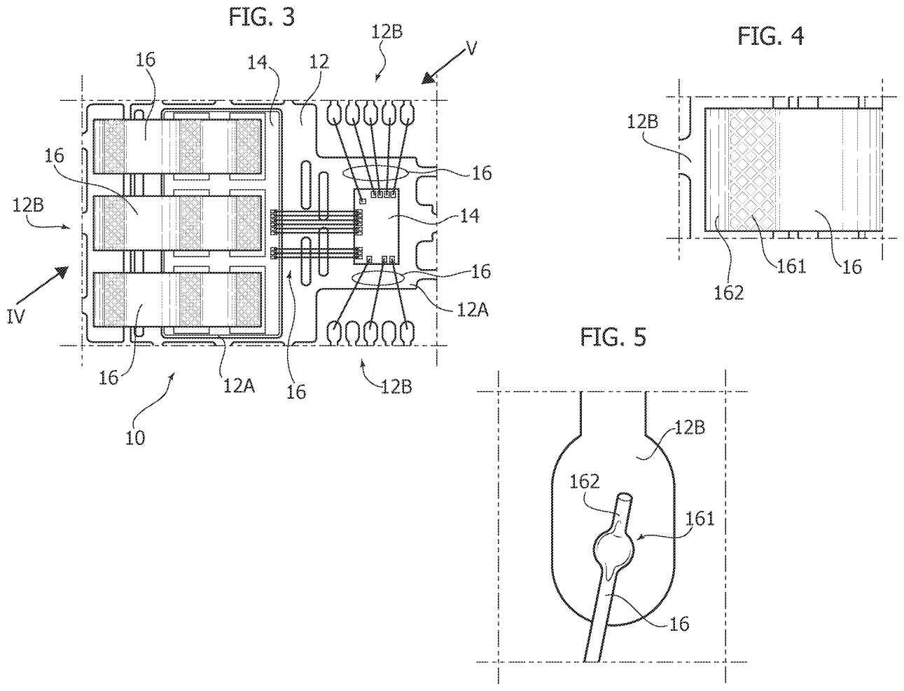

FIG. 3 is a plan view of a power semiconductor device to which embodiments of the present description may apply;

FIG. 4 is a view of the portion of FIG. 3 indicated by the arrow IV, reproduced on an enlarged scale;

FIG. 5 is a view of the portion of FIG. 3 indicated by the arrow V, reproduced on an enlarged scale;

FIGS. 6 to 12 (wherein FIG. 7 is a cross-sectional view along line VII-VII of FIG. 6) are illustrative of a possible sequence of steps in manufacturing a semiconductor device;

FIGS. 13 to 19 (wherein FIG. 14 is a cross-sectional view along line XIV-XIV of FIG. 13) are illustrative of a possible sequence of steps in manufacturing a semiconductor device according to embodiments of the present description;

FIG. 20 is a view of the portion of FIG. 19 indicated by the arrow XX, reproduced on an enlarged scale;

FIGS. 21A and 21B are perspective views illustrative of the possible result of the sequence of steps of FIGS. 13 to 19; and

FIG. 22 is illustrative of a possible variant of embodiments of the present description.

### DETAILED DESCRIPTION

Corresponding numerals and symbols in the different figures generally refer to corresponding parts unless otherwise indicated.

The figures are drawn to clearly illustrate the relevant aspects of the embodiments and are not necessarily drawn to scale.

The edges of features drawn in the figures do not necessarily indicate the termination of the extent of the feature.

In the ensuing description one or more specific details are illustrated, aimed at providing an in-depth understanding of examples of embodiments of this description. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment” or “in one embodiment” that may be present in one or more points of the present description do not necessarily refer to one and the same embodiment.

Moreover, particular conformations, structures, or characteristics may be combined in any adequate way in one or more embodiments.

The headings/references used herein are provided merely for convenience and hence do not define the extent of protection or the scope of the embodiments.

For simplicity and ease of explanation, throughout this description, and unless the context indicates otherwise, like parts or elements are indicated in the various figures with like reference signs, and a corresponding description will not be repeated for each and every figure.

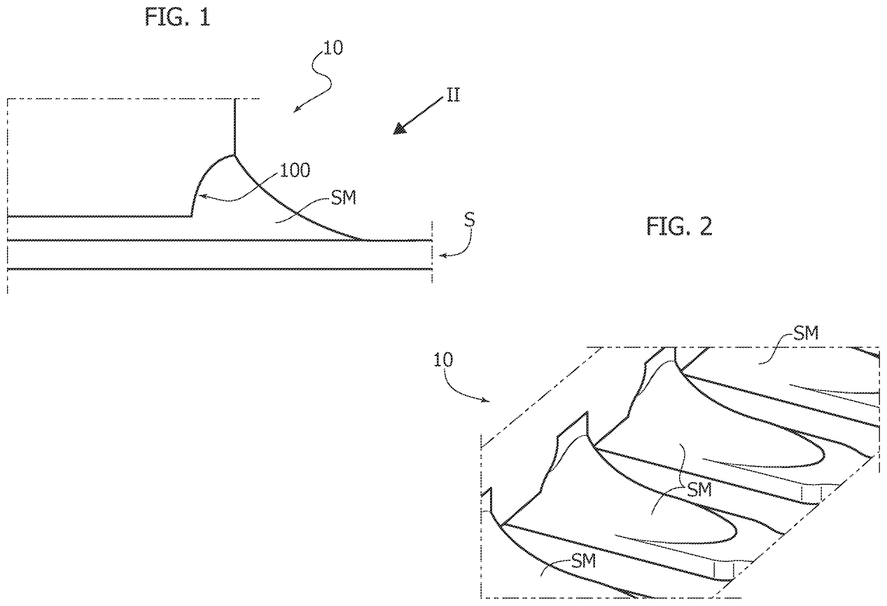

FIG. 1 is a partial cross-sectional view through a semiconductor device 10 mounted (attached) on a support member S such as a printed circuit broad (PCB).

As illustrated in FIG. 1, attachment is via solder material SM and various device packages (e.g., for the automotive market) have a geometry feature 100 on the lead sides, called wettable flanks.

This feature facilitates formation of a meniscus in the solder material SM when soldering the device 10 on a support member, e.g., PCB.

Wettable flanks facilitate automatic optical inspection insofar as the solder meniscus is visible.

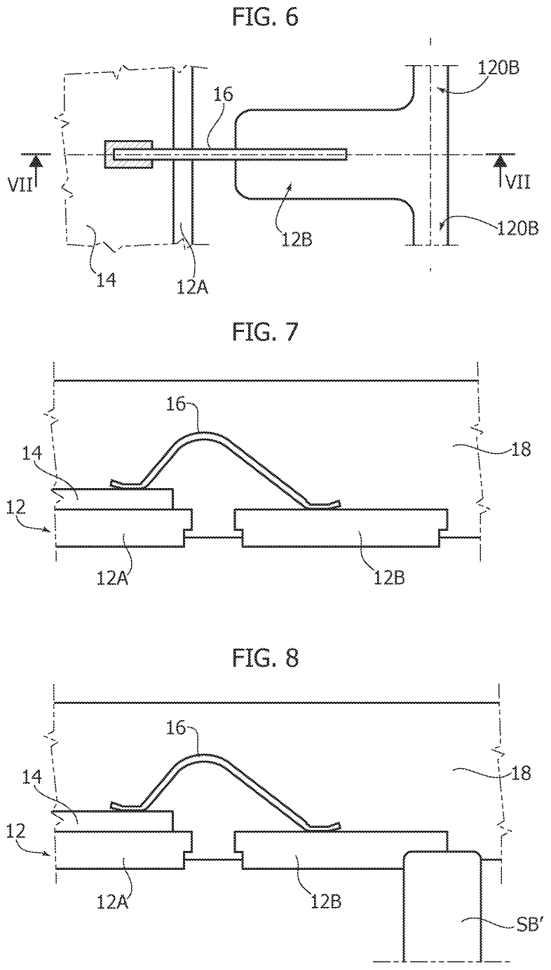

As illustrated herein by way of example, as shown in FIG. 3, a semiconductor device such as the device 10 comprises: a substrate (leadframe) 12 having one or more (integrated circuit) semiconductor chips or dice 14 arranged thereon; electrically conductive formations (wires, ribbons, clips) 16 coupling the semiconductor chip(s) 14 to leads (outer pads) in the substrate; and an insulating encapsulation (e.g., a resin) 18 molded on the assembly thus formed to complete the plastic body of the device 10.

As used herein, the terms chip/s and die/dice are regarded as synonymous.

FIGS. 3 to 5 illustrate a power semiconductor device 10 comprising a low-power section (e.g., a controller die, illustrated on the right-hand side of FIG. 3) attached on a first die pad in the leadframe 12 and a high-power section (e.g., one or more power dice illustrated on the left-hand side FIG. 3) attached on one or more die pads in the lead frame 12, with an array of leads around the die pads having the low-power and the high-power dice mounted thereon.

The current transferred from the high-power section to the output pads of the device can be significant. As shown on the left-hand side of FIG. 3, ribbons or clips 16 are thus used for that purpose in the place of wires. Wires, likewise indicated as 16 can still be used as shown on the right-hand side of FIG. 3 to provide electrical coupling to a low-power section (e.g., a controller) in the device.

The designation “leadframe” (or “lead frame”) is currently used (see, for instance the USPC Consolidated Glossary of the United States Patent and Trademark Office) to indicate a metal frame that provides support for an integrated circuit chip or die as well as electrical leads to interconnect the integrated circuit in the die or chip to other electrical components or contacts.

Essentially, a leadframe comprises an array of electrically-conductive formations (or leads, e.g., 12B) that from an outline location extend inwardly in the direction of a semiconductor chip or die (e.g., 14) thus forming an array of electrically-conductive formations from a die pad (e.g., 12A) configured to have at least one semiconductor chip or die attached thereon. This may be via conventional means such as a die attach adhesive (a die attach film or DAF, for instance).

Again, as illustrated in FIGS. 3 to 5, electrically conductive formations are provided comprising wire bonding patterns 16 coupling the low-power section (right-hand side of FIG. 3) to selected ones of the leads 12B and to the high-power section (left-hand side of FIG. 3). These wire bonding patterns are coupled to die pads provided at the front or top surfaces of the chips.

Conversely, so-called ribbons are used to couple the high-power section (left-hand side of FIG. 3) to selected ones of the leads 12B acting as (power) output pads of the device 10. Using ribbons in the place of wires accounts for the fact that the current transferred from the high-power section to the output pads in a power semiconductor device may be significant.

A device structure as discussed so far is conventional in the art, which makes it unnecessary to provide a more detailed description herein.

A single (integrated circuit) chip or die 14 mounted on a single die pad 12A will be considered throughout the rest of this description for simplicity.

The leadframe 12 is the base material support for the device 10. It is made of, e.g., copper, and shaped to accommodate semiconductor dice and generate pad connections.

Photo-etching can be advantageously used for leadframe manufacturing: a sheet or strip of copper material is etched on top and bottom side to create die pads and leads.

Pads/leads are connected together by sacrificial connecting bars. Wedge-wedge bonding could be used to bond wires. Plating treatments are also applied as desired.

Wedge(-wedge) bonding is a current designation for wire/ribbon bonding technology that use force and ultrasonic power in order to create an interconnection between a surface (e.g., a leadframe 12 or a die 14) and a wire/ribbon as designated by 16 in figures: in fact, Wedge bonding technology can be applied to both wires and ribbons.

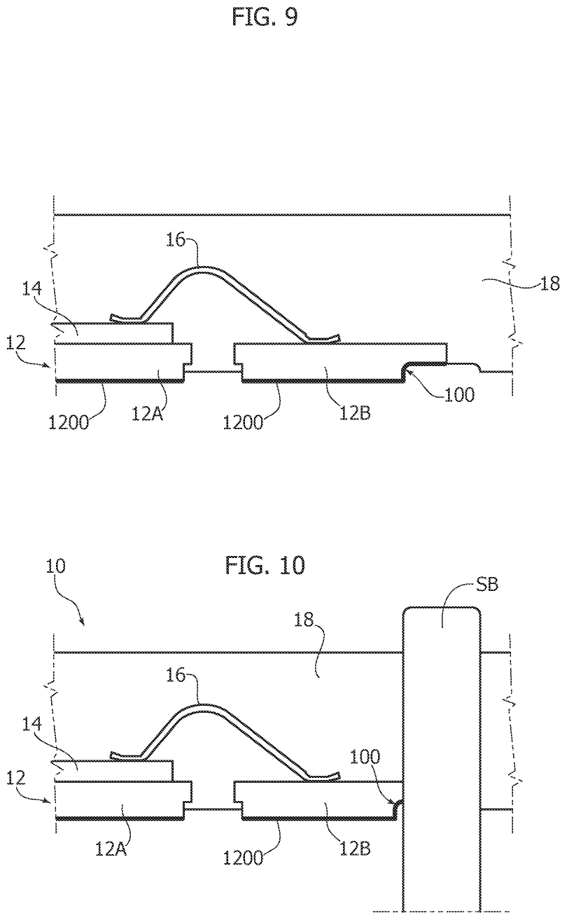

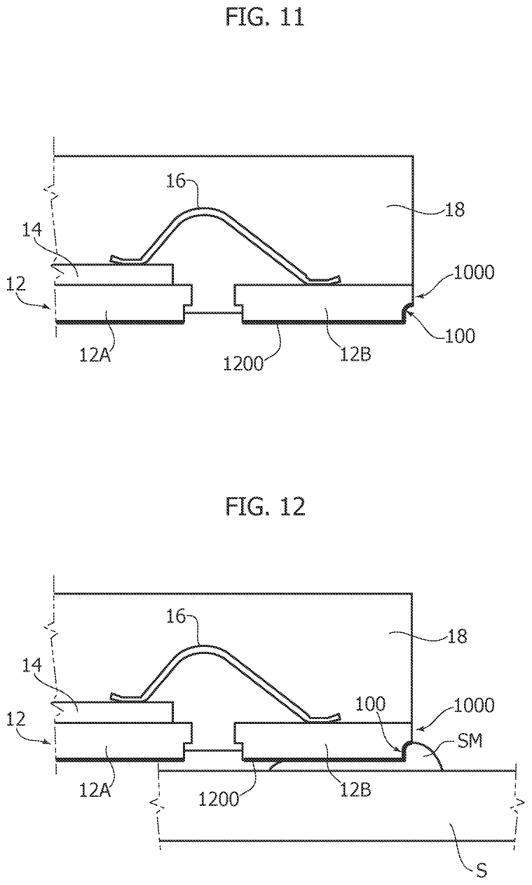

As illustrated, e.g., in FIGS. 4 and 5, the (welded) connection of a wire and/or ribbon 16 to a die/leadframe surface includes two sections: a proximal section (wedge section proper) 161, and a distal section (tail formation) 162.

The proximal wedge section 161 carries the current/signal, while distal tail 162 does not contribute appreciably to signal transport, because that section is not welded to the die/leadframe surface.

After molding of the encapsulation 18, the device package is sealed. Dice 14 and wires/ribbons 16 are no longer accessible from the outside.

Any detachment between a wire/ribbon 16 and a corresponding lead 12B, for instance, will result in a failure of the whole device 10. Wire bonding related issues may represent a major source of device failure.

A method to provide wettable flanks on a device package is by sawing.

This approach relies on the fact that, in current manufacturing processes of semiconductor devices, plural devices are manufactured together and separated into single individual device in a final singulation (sawing) step.

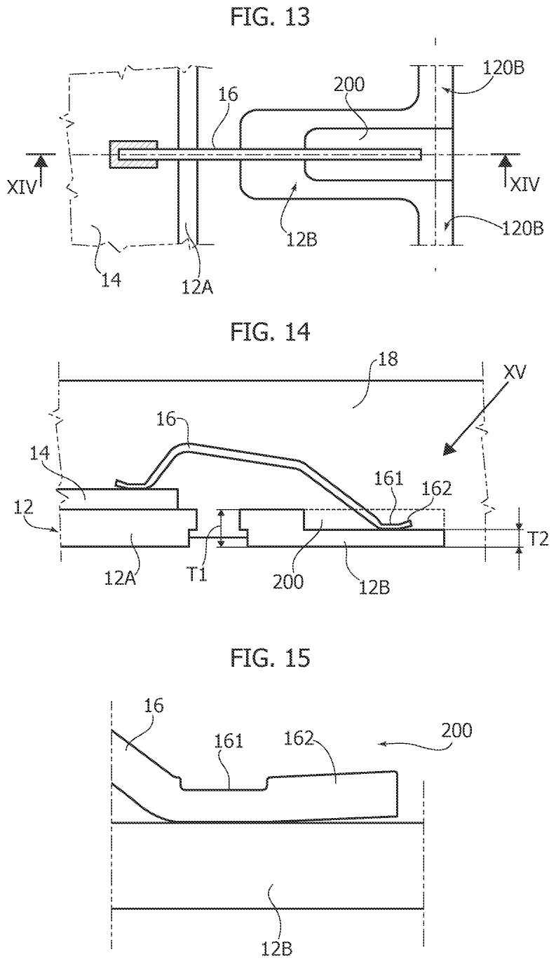

That is, after a chain of devices 10 formed on a common leadframe strip is assembled (dice, wires and molding: see FIGS. 6 and 7), individual devices 10 are separated via singulation as represented in FIG. 10 using a sawing blade SB.

As illustrated in FIGS. 8 and 9, prior to the final singulation, the leadframe 12 is partially sawn (engraved) using a circular saw SB′ (this may be the same singulation blade SB or a different blade) that partially cuts the common leadframe strip material at pad (lead) level between adjacent devices, that is, at the device flanks. Pads (leads) remain connected together via connecting bars provide to facilitate electrical connection for plating.

Plating as indicated by 1200 is applied to the whole leadframe 12 so that all exposed pad areas (die pads 12A and leads 12B) will be plated.

Final singulation as illustrated in FIG. 10 is then applied, cutting (e.g., via a saw SB) all the materials starting from the bottom or back surface of the leadframe 12 till the top of the package. As a result, each packaged device 10 is separated from manufacturing chain.

As illustrated in FIGS. 11 and 12, a device 10 thus produced will have an external flank surface plated area extending only on that part of the lead shape that does not derive from cutting during singulation: that portion of the wettable flanks produced from cutting (that is, that portion exposed as result of cutting during singulation, as indicated by 1000 in FIGS. 11 and 12) will have exposed—and unplated—leadframe material (copper) on the external package side.

As noted, solder SM is applied in order to connect the device package to a board S. Meniscus will appear after soldering.

Electrical connection between the solder SM (the board S) and wire/ribbon 16 takes place primarily through the metal (copper) lead 12B. In case of detachment between wire 16 and lead 12B, the device will likely fail with no possibility of recovery.

For simplicity a wire/lead is illustrated throughout FIGS. 6 to 22, but the same discussion also applies to a ribbon.

At least in principle, the risk of weld off/lift can be reduced keeping the assembly process as stable as possible, e.g., performing “in process control”: input and output key parameters are checked according to a process control plan, and output parameters are monitored and checked (e.g., wire/ribbon pull and shear test). Electrical testing can also be envisaged.

In process control is performed with a specific sample size and frequency: 100% checks are hardly feasible. Visual inspection of the connection between a wire and a lead can be performed before molding step only. Electrical testing can evaluate the interconnection during the test phase only: possible evolution and consequent failure of the interconnection cannot be predicted.

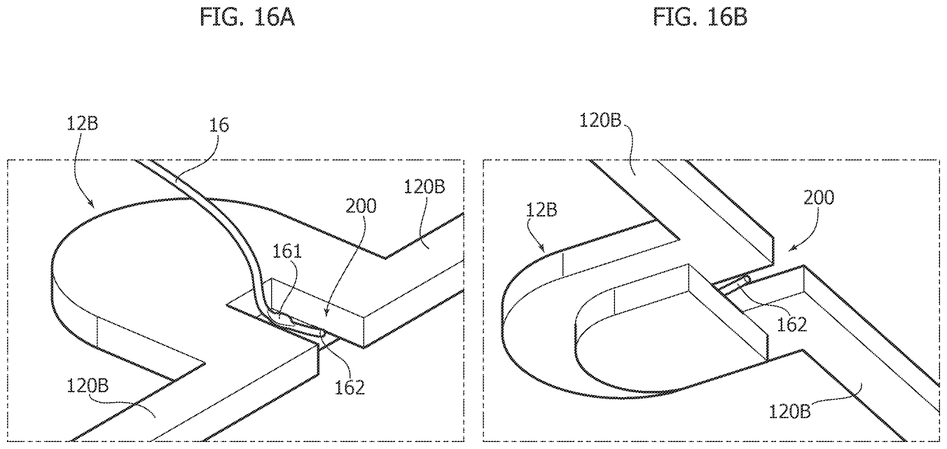

With reference to FIGS. 13-14, solutions as exemplified herein contemplate providing a recessed region 200 in the front or top surface of the leads 12B and forming the wedge bond to the wire/ribbon 16 in such dedicated recessed region of the lead.

Such a recessed area 200 can be provided, e.g., by chemical etching, coining, laser machining, or other conventional technologies known to those of skill in the art. For instance, such recessed areas or regions 200 can be formed at the leads 12B during leadframe manufacturing.

Such recessed areas or regions 200 can have different shapes.

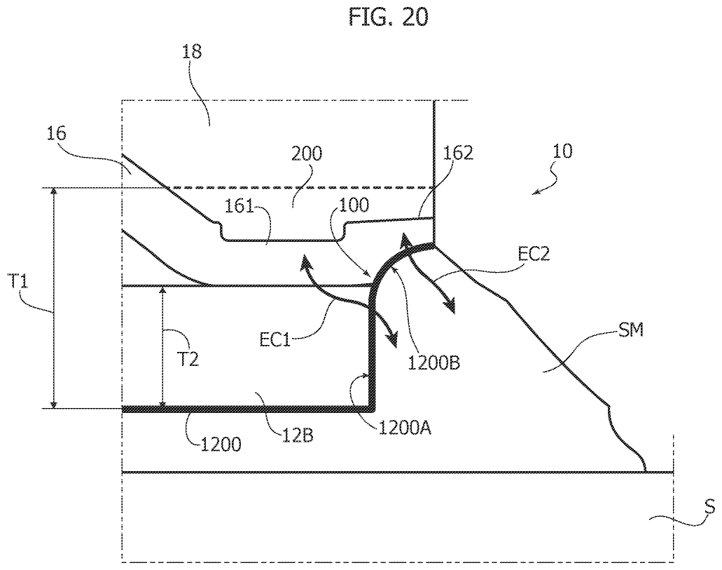

As visible in FIGS. 16A and 16B (and FIGS. 21A and 21B— that refer to a condition after removal of the sacrificial tie bars 120B) the recessed portions 200 can be provided in individual leads 12B as a (e.g., rectangular) recess etched (in a manner known per se) in the metal (e.g., copper) of the sculptured structure of the leadframe 12.

It is noted that FIGS. 16A and 16B (and FIGS. 21A and 21B as well) refer for clarity of representation: to individual leads 12B illustrated in isolation from any other neighboring part (e.g., the encapsulation 18); to leads 12B shown after a final singulation step (see FIG. 18) that results in these etched recessed being cut about their half length, thus giving rise (in mutually facing leads 12B of adjacent devices 10 manufactured simultaneously and then singulated) to half-recesses in the form of notches cut in the flanks of these devices.

It is further noted that the leads 12B visible in the schematic representations of FIGS. 16A and 16B (and FIGS. 21A and 21B) have shapes that are different from the leads 12B of FIGS. 3 to 5 or FIGS. 6 and 13. This is intended to highlight the possibility for solutions as discussed herein to be applied to leads 12B having a wide variety of shapes.

As noted, solutions as presented herein rely on the fact that in current manufacturing processes of semiconductor devices, plural devices 10 are manufactured concurrently to be separated into single individual device in a final singulation (sawing) step. That is, after a chain of devices 10 formed on a common leadframe strip is assembled (dice, wires and molding: see FIG. 13 onwards), individual devices 10 are separated via singulation as represented in FIG. 18 using a sawing blade SB.

Advantageously, the bond of the wire/ribbon 16 to the recessed portion 200 at the proximal section 161 (this may be formed, e.g., as a “second bond” in a wire bonding process where a “first bond” is formed at the chip or die 14: see, e.g., FIG. 14) extends into a “long” distal, tail formation 162 long enough to cause the tail 162 to lie at (above) the wettable flank sawing area (see, e.g., FIGS. 15, 16A and 16B).

The first sawing step (see SB′ in dashed lines in FIG. 17) will cut through the (copper) lead 12B plus a portion of wire/ribbon thickness only, which is facilitated by a well-controlled sawing cut and relative wear of the blade SB′).

Electrical connection between pads (leads) can still be maintained via a sacrificial connecting bar 120B that is still present.

Plating 1200 is again applied over the whole (back or bottom surface) of leadframe, with exposed pad/lead areas plated.

Final singulation (see the blade SB in FIG. 19) will cut through the material thickness separating the individual devices 10, removing the connecting bars 120B as well.

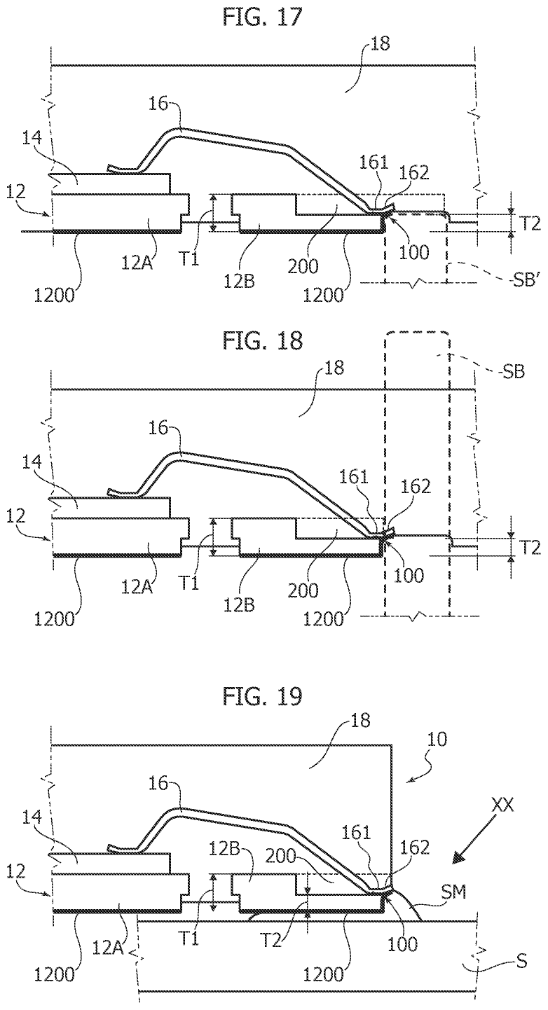

As visible in FIG. 20, a device 10 thus produced will again have an external flank surface plated area extending on that part of the lead shape that does not derive from cutting during singulation.

That external flank surface will comprise: a first (plated) portion 1200A resulting from the first (partial) cutting through the lead 12B; and a second (plated) portion 1200B resulting from the first (partial) cutting through (e.g., the tail 162 of) the wire/ribbon 16.

Only the end portion (e.g., the tail portion 162) of the wire/ribbon 16 exposed as result of cutting during singulation will have exposed—and unplated—leadframe material (copper) on the external package side.

As visible in FIGS. 21A and 21B (which represent the situation after removal of the sacrificial tie bars 120B) the recessed portions 200 can be provided in individual leads 12B as a (e.g., rectangular) recess etched (in a manner known per se) in the metal (e.g., copper) of the sculptured structure of the leadframe 12.

It is again noted that FIGS. 21A and 21B refer, for clarity of representation, to individual leads 12B illustrated in isolation from any other neighboring part (e.g., the encapsulation 18).

These leads 12B are shown after a final singulation step (see FIG. 18) that results in these etched recessed being cut about their half length, thus giving rise (in mutually facing leads 12B of adjacent devices 10 manufactured simultaneously and then singulated) to half-recesses in the form of notches cut in the flanks of these devices.

The final device 10 will thus have a plated area shape for wettable flanks (except for a small portion of wire/ribbon) on the external package side.

Solder can thus be applied to connect the device 10 to the board S. Meniscus will be produced in the solder SM as a result of soldering.

As exemplified in FIG. 20, electrical connection between the solder SM (the board S) and the wire/ribbon 16 will occur: via the (copper) lead 12B as exemplified by EC1, and via an additional connection path between the wire/ribbon 16 and the solder SM as exemplified by EC2.

In case of detachment between the wire/ribbon 16 and the lead 12B (connection EC1 fail), the device 10 can remain operable through the solder to wire/ribbon 16 connection (connection EC2).

To summarize, solutions as presented herein involve arranging at least one semiconductor die 14 on a die pad 12A at a first surface of a support substrate (leadframe) 12.

The support substrate 12 has a first thickness (indicated as T1 in the figures) between the first surface and a second surface opposite the first surface.

The support substrate (leadframe) 12 comprises an array of electrically conductive leads 12B around the die pad 12A.

Terminal recesses 200 (that is, recesses located at or in proximity of the distal end of the lead 12B concerned) are formed in (at least some of) the electrically conductive leads 12B in the array at the first surface of the leadframe 12 (that is, the surface onto which the die 14 is mounted).

At the terminal recesses 200, the leads 12B have a second thickness (indicated as T2 in the figures) that is less than the first thickness T1.

The electrically conductive, elongated formations such as the wires or ribbons 16 have coupling ends 161, 162 to the electrically conductive leads 12B arranged at the recesses 200.

Partially cutting (engraving) the leadframe 12 starting from the second surface as presented by reference SB′ is carried out at the terminal recesses 200 with a cutting depth Tx that lies between the first thickness T1 and the second thickness T2 (T1>Tx>T2).

Partial cutting SB′ thus produces exposed surfaces of the support substrate (see reference 1200A) and the coupling ends (see reference 1200B) of the wires or ribbons 16.

The insulating encapsulation 18 molded onto the semiconductor die 14 arranged on the die pad 12A at the first surface of the support substrate 12 leaves uncovered (as solder wettable flanks) the exposed surfaces of the support substrate 1200A and the coupling ends 1200B of the electrically conductive elongated formations 16 produced by partial cutting.

As illustrated, the coupling ends 161, 162 of the wires or ribbons 16 to respective leads 12B, comprise, arranged in the terminal recesses 200: proximal portions 161 (e.g., wedge) bonded to selected ones of the electrically conductive leads 12B at the recesses 200, and distal portions 162 projecting from the proximal portions 161 at the recesses 200.

As illustrated, the distal portions 162 are exempt from bonding to the leads 12B.

Advantageously, partial cutting SB′ at the terminal recesses 200 with a cutting depth between the first thickness (T1) and the second thickness (T2) takes place at the distal portions 162, thus producing exposed surfaces of the support substrate (leadframe, see reference 1200A) and of the distal portions 162 the coupling ends of the wires or ribbons 16.

As exemplified in FIGS. 19 and 20, the device 10 with the support substrate 12 having the semiconductor die or dice 14 arranged on the die pad 12A can be mounted onto a mounting member (such as a printed circuit board S) via solder material SM that wets and forms a solder meniscus at both exposed surfaces of the leadframe 12 (see reference 1200A) and of the coupling ends (see reference 1200B) of the wires or ribbons 16.

Embodiments as presented herein can be applied to any package that use a wire or ribbon welded through wedge-wedge bonding technology and take advantage from having a wettable flank.

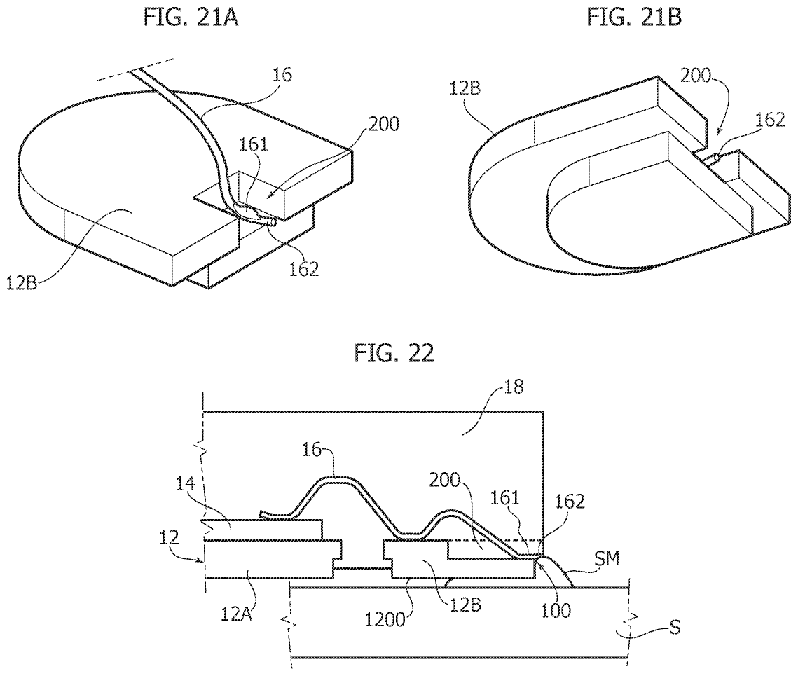

FIG. 22 is illustrative of a possible variant of embodiments of the present description where double or plural bonding is applied, e.g., to a wire 16. Here, a first bonding of the wire 16 is made to the upper surface of the leads 12B at a location outside of the recess 200 and a second bonding of the wire 16 is made to the upper surface of the leads 12B at a location within the recess 200.

It will be appreciated that the (first, partial) sawing line SB′ can pass through proximal section 161 of the bond, thus also in the absence of a “long” distal, tail formation 162.

Wedge(-wedge) bonding as discussed herein can be performed using wires or ribbons made of aluminum, copper, gold or other materials suited to be bonded, e.g., with an ultrasonic process.

Solutions as discussed herein provide improved package reliability, e.g., as a result of solder meniscus SM directly connected to the wire/ribbon 16.

No additional process steps or costs are involved: solutions as discussed herein can be implemented using existing wire bonding machines.

Wire/ribbon tails can be made accessible from the outside of the device package. Wettable flanks may have a direct connection between wire and solder, when mounted on board.

Wettable flanks are a desirable specification of certain automotive products.

Wettable flanks facilitate automatic inspection in order to check the correct welding of the package to the board.

Using wedge bonding technology together with a special lead design (recessed area), facilitates exposing a wire or ribbon portion (e.g., a “tail”) outside the package sides. Those portions can be incorporated together with the leads by the solder, when a device is assembled on a board. In that way, the wires/ribbons are connected with respective leads and with the solder as well. In case a first connection (e.g., EC1) fails for any reason (wedge lift), a second connection (e.g., EC2) can compensate the first, thus maintaining device operation. Device reliability is improved.

Visual inspection on the package side (and/or 3D x-ray analysis), possibly facilitated by cross-section and/or decapsulation can reveal the lead recessed areas 200.

Without prejudice to the underlying principles, the details and embodiments may vary, even significantly, with respect to what has been described by way of example only without departing from the extent of protection.

The claims are an integral part of the technical teaching provided in respect of the embodiments.

The extent of protection is determined by the annexed claims.

1. A method, comprising:
arranging a semiconductor die on a die pad at a first surface of a support substrate, the support substrate having a first thickness between the first surface and a second surface opposite the first surface and comprising an array of electrically conductive leads around the die pad, wherein the electrically conductive leads in the array of electrically conductive leads have terminal recesses at the first surface of the support substrate, wherein at said terminal recesses said electrically conductive leads in the array of electrically conductive leads have a second thickness less than said first thickness;
electrically coupling the semiconductor die with said electrically conductive leads in the array of electrically conductive leads via electrically conductive elongated formations having ends coupled to the electrically conductive leads in the array of electrically conductive leads arranged in said terminal recesses; and
partially cutting the support substrate starting from the second surface, wherein partially cutting is performed at said terminal recesses and with a cutting depth that is between the first thickness and the second thickness, wherein the partial cutting produces exposed surfaces of the support substrate and the ends of the electrically conductive elongated formations at said terminal recesses.

2. The method of claim 1, further comprising molding an insulating encapsulation onto the at least one semiconductor die arranged on the die pad at the first surface of the support substrate, wherein the insulating encapsulation leaves uncovered the exposed surfaces of the support substrate and the ends of the electrically conductive elongated formations produced by said partially cutting.

3. The method of claim 1, wherein the electrically conductive elongated formations having ends arranged in said terminal recesses comprise wires.

4. The method of claim 1, wherein the electrically conductive elongated formations having ends arranged in said terminal recesses comprise ribbons.

5. The method of claim 1, wherein said ends of the electrically conductive elongated formations comprise:
proximal portions bonded to electrically conductive leads in the array of electrically conductive leads at said recesses; and
distal portions projecting distally of the proximal portions at said recesses in the absence of bonding of the distal portion to electrically conductive leads in the array of electrically conductive leads.

6. The method of claim 5, further comprising wedge bonding said proximal portions to electrically conductive leads in the array of electrically conductive leads at said recesses.

7. The method of claim 5, wherein partially cutting at said terminal recesses with a cutting thickness between the first thickness and the second thickness is performed at said distal portions wherein the partial cutting produces exposed surfaces of the support substrate and of the distal portions of the ends of the electrically conductive elongated formations.

8. The method of claim 5, further comprising applying a plating to the distal portions at said ends of the electrically conductive elongated formations and to the electrically conductive leads in the array of electrically conductive leads at said recesses

9. The method of claim 1, further comprising applying a plating to the exposed surfaces of the support substrate and to the ends of the electrically conductive elongated formations at said terminal recesses.

10. The method of claim 1, further comprising mounting the support substrate having the at least one semiconductor die arranged on the die pad onto a mounting member via solder material that wets and forms a solder meniscus at both exposed surfaces of the support substrate and of the ends of the electrically conductive elongated formations.

11. A device, comprising:
a support substrate having a first thickness between the first surface and a second surface opposite the first surface and comprising a die pad and an array of electrically conductive leads around the die pad;
a semiconductor die arranged on the die pad;
terminal recesses in the electrically conductive leads of the array of electrically conductive leads at the first surface of the support substrate, wherein at said terminal recesses said electrically conductive leads in the array of electrically conductive leads have a second thickness less than said first thickness;
electrically conductive elongated formations electrically coupling the semiconductor die with said electrically conductive leads in the array of electrically conductive leads, the electrically conductive elongated formations having ends coupled to the electrically conductive leads in the array of electrically conductive leads arranged in said terminal recesses; and
a partial cut in the support substrate starting from the second surface, the partial cut being located at said terminal recesses and with a cutting depth between the first thickness and the second thickness, wherein the partial cut leaves exposed surfaces of the support substrate and the ends of the electrically conductive elongated formations.

12. The device of claim 11, further comprising an insulating encapsulation molded onto the semiconductor die arranged on the die pad at the first surface of the support substrate, wherein the insulating encapsulation leaves uncovered the exposed surfaces of the support substrate and the ends of the electrically conductive elongated formations.

13. The device of claim 11, wherein the electrically conductive elongated formations having ends arranged in said terminal recesses comprise wires.

14. The device of claim 11, wherein the electrically conductive elongated formations having ends arranged in said terminal recesses comprise ribbons.

15. The device of claim 11, wherein said ends to the electrically conductive elongated formations arranged in said terminal recesses comprise:
proximal portions bonded to electrically conductive leads in the array of electrically conductive leads at said recesses; and
distal portions projecting distally of the proximal portions at said recesses in the absence of bonding of the distal portion to electrically conductive leads in the array of electrically conductive leads.

16. The device of claim 11, further comprises a plated layer on the exposed surfaces of the support substrate and to the ends of the electrically conductive elongated formations.

17. An assembly, comprising:
a semiconductor device mounting member; and
a device mounted onto said mounting member via solder material;
wherein the device comprises:
a support substrate having a first thickness between the first surface and a second surface opposite the first surface and comprising a die pad and an array of electrically conductive leads around the die pad;
a semiconductor die arranged on the die pad;
terminal recesses in the electrically conductive leads of the array of electrically conductive leads at the first surface of the support substrate, wherein at said terminal recesses said electrically conductive leads in the array of electrically conductive leads have a second thickness less than said first thickness;
electrically conductive elongated formations electrically coupling the semiconductor die with said electrically conductive leads in the array of electrically conductive leads, the electrically conductive elongated formations having ends coupled to the electrically conductive leads in the array of electrically conductive leads arranged in said terminal recesses; and
a partial cut in the support substrate starting from the second surface, the partial cut being located at said terminal recesses and with a cutting depth between the first thickness and the second thickness, wherein the partial cut leaves exposed surfaces of the support substrate and the ends of the electrically conductive elongated formations;
wherein the solder material exhibits a solder meniscus at exposed surfaces of both the support substrate and the ends of the electrically conductive elongated formations.

18. The assembly of claim 17, wherein the electrically conductive elongated formations having ends arranged in said terminal recesses comprise wires.

19. The assembly of claim 17, wherein the electrically conductive elongated formations having ends arranged in said terminal recesses comprise ribbons.

20. The assembly of claim 17, wherein said ends to the electrically conductive leads in the array of electrically conductive leads arranged in said terminal recesses comprise:
proximal portions bonded to electrically conductive leads in the array of electrically conductive leads at said recesses; and
distal portions projecting distally of the proximal portions at said recesses in the absence of bonding of the distal portion to electrically conductive leads in the array of electrically conductive leads.

21. A support substrate having a first thickness between a first surface and a second surface opposite the first surface and comprising an array of electrically conductive leads around a die pad, the support substrate having terminal recesses in electrically conductive leads in the array of electrically conductive leads at the first surface of the support substrate, wherein at said terminal recesses in said electrically conductive leads in the array of electrically conductive leads have a second thickness less than said first thickness, said terminal recesses configured to have arranged therein the coupling ends of electrically conductive elongated formations configured to electrically couple a semiconductor die mounted to the die pad with said electrically conductive leads in the array of electrically conductive leads.
